(19) United States
(12) Patent Application Publication
(10) Pub. No.: US 2015/0323250 A1
(43) Pub. Date: Nov. 12, 2015

(54) SUBSTRATE PROCESSING APPARATUS, DEPOSIT REMOVING METHOD OF SUBSTRATE PROCESSING APPARATUS AND RECORDING MEDIUM

(71) Applicant: Tokyo Electron Limited, Tokyo (JP)

(72) Inventors: Tsuyoshi Mizuno, Koshi City (JP); Yoichi Tokunaga, Koshi City (JP); Hiromitsu Nanba, Koshi City (JP); Tatuhiro Ueki, Koshi City (JP); Fitrianto, Albany, NY (US)

(21) Appl. No.: 14/707,145

(22) Filed: May 8, 2015

(30) Foreign Application Priority Data
May 9, 2014 (JP) 2014-098039

(51) Int. Cl. F26B 3/20; H01L 21/67

(52) U.S. Cl. CPC F26B 3/20; H01L 21/67075

(57) ABSTRACT

A particle can be suppressed from being generated by removing a processing liquid or crystals caused by the processing liquid which adhere to a cover member. A substrate processing apparatus includes a substrate holding unit 3 configured to hold a substrate W; a processing liquid supply unit 7 configured to supply a processing liquid onto the substrate W held in the substrate holding unit 3; and a cover member 5 which has a ring shape and is disposed to face a peripheral portion of the substrate held in the substrate holding unit 3. Further, the cover member 5 is equipped with a heater 701 configured to heat the cover member 5.

### CROSS-REFERENCE TO RELATED APPLICATION

This application claims the benefit of Japanese Patent Application No. 2014-098039 filed on May 9, 2014, the entire disclosures of which are incorporated herein by reference.

### TECHNICAL FIELD

The embodiments described herein pertain generally to a technique of processing a peripheral portion of a substrate by supplying a processing liquid onto the peripheral portion thereof.

### BACKGROUND

In a semiconductor device manufacturing process, a substrate processing, in which an unnecessary film or a contaminant is removed from a peripheral portion of a semiconductor wafer (hereinafter, simply referred to as “wafer”) as a processing target substrate by supplying a processing liquid such as a chemical liquid onto the peripheral portion of the wafer while rotating the wafer, is performed. There is known a substrate processing apparatus including a cover member that covers a top surface of the wafer when performing the substrate processing (see, for example, Patent Document 1). This cover member rectifies a gas flowing in the vicinity of the peripheral portion of the wafer and increases a flow velocity of the gas, so that the processing liquid dispersed from the wafer is suppressed from adhering to the top surface of the wafer again.

Patent Document 1: Japanese Patent Laid-open Publication No. 2013-128014

In the conventional substrate processing apparatus, however, the processing liquid dispersed from the wafer or the processing liquid in the form of mist may adhere to a surface of the cover member. These processing liquids react with each other to be crystallized, and a part of the crystallized processing liquids may be peeled off from the surface of the cover member and fall down onto the surface of the wafer, so that a particle is generated.

### SUMMARY

In view of the foregoing problems, exemplary embodiments provide a technique of suppressing a particle from being generated by removing a processing liquid or crystals caused by the processing liquid which adhere to a cover member.

In one exemplary embodiment, a substrate processing apparatus includes a substrate holding unit configured to hold a substrate; a processing liquid supply unit configured to supply a processing liquid onto the substrate held in the substrate holding unit; and a cover member which has a ring shape and is disposed to face a peripheral portion of the substrate held in the substrate holding unit. Further, the cover member is equipped with a heater.

According to the exemplary embodiments, by removing the processing liquid or the crystals caused by the processing liquid which adhere to the cover member, the particle can be suppressed from being generated.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a longitudinal side view of a substrate processing apparatus according to an exemplary embodiment;

FIG. 2 is a plane view illustrating a cover member, an elevating device and a processing fluid supply unit of the substrate processing apparatus shown in FIG. 1;

FIG. 3 is an enlarged cross sectional view illustrating a region in the vicinity of an outer peripheral portion of a wafer shown in a right side of FIG. 1;

FIG. 4A and FIG. 4B are diagrams illustrating nozzles;

FIG. 5 is a flow chart for describing a standard liquid processing operation according to the exemplary embodiment;

FIG. 6 is a flow chart for describing a liquid processing operation including a heating processing according to a first exemplary embodiment; and

FIG. 7 is a flow chart for describing a liquid processing operation including a heating processing according to a second exemplary embodiment.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

A substrate processing apparatus according to an exemplary embodiment will be described in detail with reference to the accompanying drawings.

### First Exemplary Embodiment

In the present exemplary embodiment, there will be described a substrate processing apparatus configured to supply a chemical liquid onto a surface of a wafer W as a circular substrate on which semiconductor devices are to be formed and configured to remove an unnecessary film formed on a peripheral portion of the wafer W.

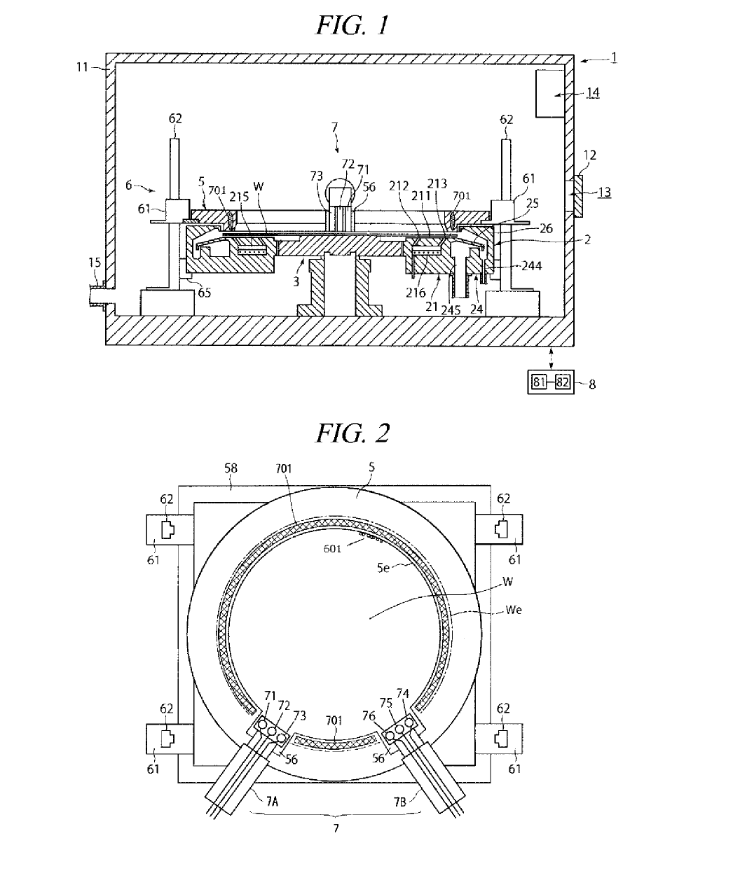

As depicted in FIG. 1 and FIG. 2, a substrate processing apparatus 1 includes a wafer holding unit 3 configured to hold the wafer W horizontally such that the wafer W is rotatable about a vertical axis; a cup body 2 surrounding the wafer W held in the wafer holding unit 3 and configured to receive the processing liquid dispersed from the wafer W; a ring-shaped cover member 5 configured to cover a peripheral portion of a top surface of the wafer W held in the wafer holding unit 3; an elevating device (moving device) 6 configured to move the cover member 5 up and down; and a processing fluid supply unit 7 configured to supply a processing fluid to the wafer W held in the wafer holding unit 3.

The aforementioned components of the substrate processing apparatus 1, i.e., the cup body 2, the wafer holding unit 3, and the cover member 5 are accommodated in a single housing 11. A clean air supply unit 14 configured to supply a clean air from the outside of the housing 11 is provided near a ceiling portion of the housing 11. Further, an exhaust port 15 through which an atmosphere within the housing 11 is exhausted is formed near a bottom portion of the housing 11. With this configuration, a downflow of the clean air that flows from an upper portion of the housing 11 toward a lower portion thereof is formed within the housing 11. A carry-in/out opening 13 which can be opened or closed by a shutter 12 is formed at a sidewall of the housing 11. A transfer arm of a non-illustrated wafer transfer device which is provided at the outside of the housing 11 is capable of passing through the carry-in/out opening 13 while holding the wafer W thereon. The wafer holding unit 3 serves as a circular plate-shaped vacuum chuck, and a top surface of the wafer holding unit 3 serves as a wafer attracting surface. The wafer holding unit 3 can be rotated at a desired speed by a non-illustrated rotation driving device.

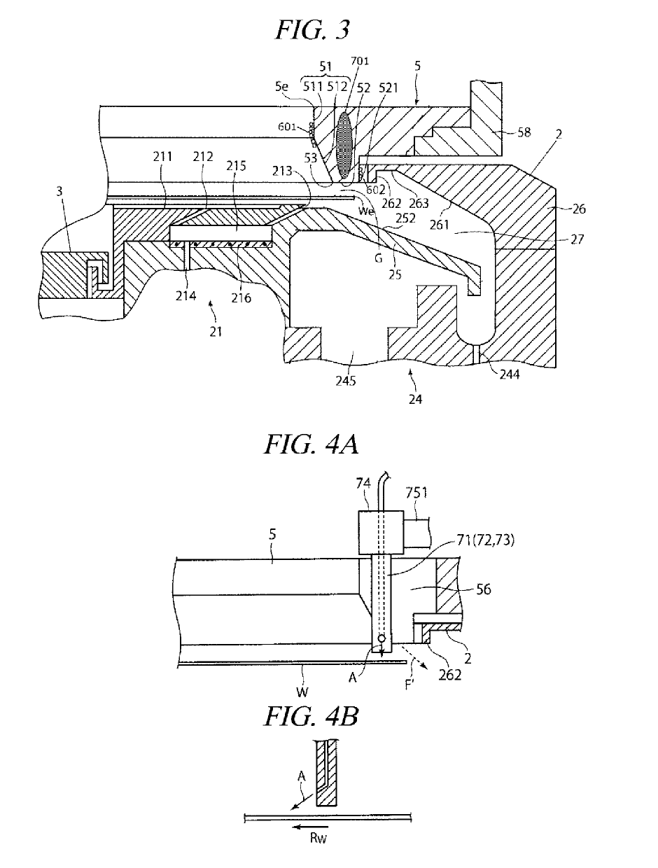

As shown in FIG. 3, the cup body 2 is a circular ring-shaped member having a bottom and is disposed to surround an outer periphery of the wafer holding unit 3. The cup body 2 is configured to receive and collect the chemical liquid which is dispersed toward the outside of the wafer W after supplied to the wafer W and configured to drain out the received chemical liquid to the outside.

A minute gap (having a height of, e.g., 2 mm to 3 mm) is formed between a bottom surface of the wafer W held in the wafer holding unit 3 and a top surface 211 of an inner-side portion 21 of the cup body 2 that faces the bottom surface of the wafer W. Two gas discharge openings 212 and 213 are opened to the top surface 211 facing the wafer W. These two gas discharge openings 212 and 213 are continuously extended along a large-diameter circumference and a small-diameter circumference, which are concentric with each other, respectively. The gas discharge openings 212 and 213 are configured to discharge an N₂ gas (a heated nitrogen gas) toward the bottom surface of the wafer W outwardly in a radial direction and upwardly in an inclined direction.

The N₂ gas is supplied into a circular ring-shaped gas diffusion space 215 from a single or a multiplicity of gas inlet lines 214 (only one is illustrated) formed in the inner-side portion 21 of the cup body 2. The N₂ gas flows within the gas diffusion space 215 while diffused in a circumferential direction and then is discharged from the gas discharge openings 212 and 213. A heater 216 is provided adjacent to the gas diffusion space 215. The N₂ gas is heated while it flows within the gas diffusion space 215 and, then, is discharged from the gas discharge openings 212 and 213. The N₂ gas discharged from the gas discharge opening 213 located at an outer position in the radial direction heats a peripheral portion of the wafer W as a target processing portion to accelerate a reaction with the chemical liquid, and suppresses mist of the processing liquid dispersed after discharged toward the front surface (top surface) of the wafer W from flowing to the rear surface (bottom surface) of the wafer W. Meanwhile, the N₂ gas discharged from the gas discharge opening 212 located at an inner position in the radial direction suppresses deformation of the wafer W that can be caused when only the peripheral portion of the wafer W is heated under the absence of the gas discharge opening 212 and when a negative pressure is generated in the vicinity of the bottom surface of the wafer W at a central portion thereof.

A drain path 244 and an exhaust path 245 are connected to an outer-side portion 24 of the cup body 2. A ring-shaped guide plate 25 is extended outwardly in the radial direction from an outer peripheral portion (a position under the periphery of the wafer W) of the inner-side portion 21 of the cup body 2. Further, an outer peripheral wall 26 is provided at an outer peripheral portion of the outer-side portion 24 of the cup body 2. The outer peripheral wall 26 receives, on its inner peripheral surface, a fluid (liquid droplets, gases, a mixture thereof, etc.) dispersed outwards from the wafer W and guides the dispersed fluid downwards. The outer peripheral wall 26 includes a fluid receiving surface 261 and a returning portion 262 extended downward from an upper end portion of the fluid receiving surface 261. The fluid receiving surface 261 is tilted at an angle of 25° to 30° from a horizontal plane and is inclined to become lower in height as it goes outwards in the radial direction. Further, an exhaust path 27, through which the gases (air, N₂ gas, etc.) and the liquid droplets dispersed from the wafer W are flown, is formed between a top surface 252 of the guide plate 25 and the fluid receiving surface 261. A top opening of the cup body 2 is demarcated by an inner peripheral surface of the returning portion 262. A diameter of the top opening is slightly larger than a diameter of the wafer W. The mixture fluid of the gases and the liquid droplets introduced into a space under the guide plate 25 is separated, and the liquid droplets are drained out through the drain path 244 and the gases are exhausted through the exhaust path 245.

The cover member 5 is a ring-shaped member provided to face the peripheral portion of the top surface of the wafer W held in the wafer holding unit 3 when the processing is performed. The cover member 5 rectifies a gas that is introduced into the cup body 2 after flowing in the vicinity of the peripheral portion of the top surface of the wafer W and increases a flow velocity of the gas, so that the processing liquid dispersed from the wafer W is suppressed from adhering to the top surface of the wafer W again.

As depicted in FIG. 3, the cover member 5 has an inner peripheral surface 51; and a horizontal bottom surface 52 that faces the wafer W. The inner peripheral surface 51 includes a vertically extended upper-side surface portion 511; and a lower-side surface portion 512 which is inclined outwards in the radial direction of the wafer W as it approaches the wafer W. A minute gap G is formed in the vertical direction between the horizontal bottom surface 52 and the top surface of the wafer W. An outer periphery 521 of the cover member 5 is located at an outer position than an outer peripheral end We of the wafer W in the radial direction thereof. Further, by way of non-limiting example, the peripheral portion of the wafer W as a target cleaning portion is a region within 3 mm from the outer peripheral end We of the wafer W in the radial direction and is covered by the horizontal bottom surface 52.

A state where the wafer W is held in the wafer holding unit 3 and the cover member 5 is located at a processing position is illustrated in a plan view of FIG. 2. In FIG. 2, the outer peripheral end (edge) We hidden from view by being covered with the cover member 5 is indicated by a dashed dotted line. Further, a reference numeral 5e denotes an inner periphery of the cover member 5.

As depicted in FIG. 1 and FIG. 2, the elevating device 6 configured to move the cover member 5 up and down includes a plurality (four in the present exemplary embodiment) of sliders 61 provided at a supporting body 58 that supports the cover member 5; and guide supporting columns 62 extended through the respective sliders 61 in the vertical direction. Each slider 61 is connected with a cylinder motor (not shown). By driving the cylinder motor, the sliders 61 are moved up and down along the guide supporting columns 62, so that the cover member 5 can be moved up and down. The cup body 2 is supported by a lifter 65 that forms a part of a cup elevating device (not shown). If the lifter 65 is moved downwards from a state shown in FIG. 1, the cup body 2 is lowered down, and the wafer W can be transferred between the transfer arm (not shown) of the wafer transfer device and the wafer holding unit 3.

Now, referring to FIG. 1, FIG. 2, FIG. 4A and FIG. 4B, the processing fluid supply unit 7 will be elaborated. As clearly depicted in FIG. 2, the processing fluid supply unit 7 is composed of a processing fluid supply unit 7A and a processing fluid supply unit 7B. In FIG. 1, only the processing fluid supply unit 7A is illustrated and the processing fluid supply unit 7B is omitted. The processing fluid supply unit 7A includes a chemical liquid nozzle 71 configured to discharge a SC-1 liquid as a mixture solution of ammonia, hydrogen peroxide and pure water; and a rinse nozzle 72 configured to discharge a rinsing liquid (DIW (pure water) in the present exemplary embodiment). This processing fluid supply unit 7A serves as a processing liquid supply unit. Further, the processing fluid supply unit 7A further includes a gas nozzle 73 configured to discharge a drying gas (N₂ gas in the present exemplary embodiment) and also serves as a gas supply unit. The processing fluid supply unit 7B includes a chemical liquid nozzle 74 configured to discharge a HF liquid; and a rinse nozzle 75 configured to discharge a rinsing liquid, and serves as a processing liquid supply unit. Further, the processing fluid supply unit 7B further includes a gas nozzle 76 that discharges a drying gas, and serves as a gas supply unit.

As shown in FIG. 2 and FIG. 4A, the nozzles 71 to 73 of the processing fluid supply unit 7A are accommodated in a recess portion 56 formed in an inner peripheral surface of the cover member 5. Each of the nozzles 71 to 73 is oriented diagonally downward, as illustrated by an arrow A in FIG. 4B and discharges a processing fluid such that a discharge direction indicated by the arrow A has a component in a rotation direction Rw of the wafer. The aforementioned processing fluids from a non-illustrated processing fluid supply device are supplied into the respective nozzles 71 to 73. The processing fluid supply unit 7B also has the same configuration as that of the processing fluid supply unit 7A.

As schematically shown in FIG. 1, the substrate processing apparatus 1 includes a controller (control unit) 8 configured to operate the overall operation of the substrate processing apparatus 1. The controller 8 controls operations of all functional components (e.g., the non-illustrated rotation driving device, the elevating device 6, the wafer holding unit 3, the various kinds of the processing fluid supplying devices, etc.) of the substrate processing apparatus 1. The controller 8 may be implemented by, for example, a general-purpose computer as a hardware and programs (an apparatus control program, processing recipes, etc.) for operating the computer as a software. The software may be stored in a recording medium, such as a hard disc drive which is fixed in the computer, or stored in a recording medium, such as a CD-ROM, a DVD, a flash memory, etc., which is set in the computer in a detachable manner. The recording medium is indicated by a reference numeral 81 in FIG. 1. When necessary, a processor 82 retrieves and executes a preset processing recipe from the recording medium 81 based on an instruction from a non-illustrated interface, so that the individual functional components of the substrate processing apparatus 1 are operated under the control of the controller 8 and a predetermined processing is performed.

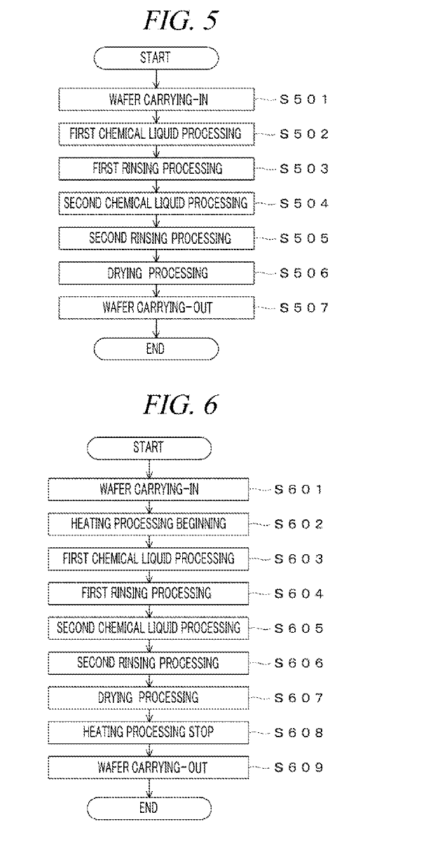

Now, an operation of a commonly known standard liquid processing performed in the substrate processing apparatus 1, i.e., an operation of a liquid processing without including a heating processing for deposit removal will be explained with reference to a flow chart of FIG. 5. The operation is performed under the control of the controller 8. This standard liquid processing is performed for a single set of 25 sheets of wafers W, and the flow chart of FIG. 5 describes a processing operation for a single sheet of wafer W in the single set. Further, in the present exemplary embodiment, a heating processing of removing a deposit is further performed in addition to the standard liquid processing, and details of this heating processing will be elaborated later.

(Wafer Carrying-in (Process S501))

First, the cover member 5 is placed at a retreat position (at a position higher than the position shown in FIG. 1) by the elevating device 6, and the cup body 2 is lowered by the lifter 65 of the cup elevating device. Then, after the shutter 12 of the housing 11 is opened, the transfer arm (not shown) of the external wafer transfer device enters the housing 11, and the wafer W held by the transfer arm is located at a position directly above the wafer holding unit 3. Thereafter, the transfer arm is lowered to a position lower than the top surface of the wafer holding unit 3, and the wafer W is placed on the top surface of the wafer holding unit 3. Then, the wafer W is attracted to and held in the wafer holding unit 3. Afterwards, the empty transfer arm is retreated out of the housing 11. Then, the cup body 2 is moved upward and returned to the position shown in FIG. 1, and the cover member 5 is lowered down to a processing position shown in FIG. 1. Through these sequences, the carrying-in of the wafer is completed, and a state shown in FIG. 1 is obtained.

(First Chemical Liquid Processing (Process S502))

Subsequently, a first chemical liquid processing on the wafer is performed. The wafer W is rotated, and by discharging an N₂ gas from the gas discharge openings 212 and 213 of the cup body 2, the wafer W, particularly, the peripheral portion of the wafer W as a processing target portion is heated to a preset temperature (e.g., to 60° C.) suitable for the chemical liquid processing. If the wafer W is heated sufficiently, a chemical liquid SC1 is supplied onto the peripheral portion of the top surface (device formation surface) of the wafer W from the chemical liquid nozzle 71 of the processing fluid supply unit 7A while rotating the wafer W, so that an unnecessary film on the peripheral portion of the top surface of the wafer is removed.

(First Rinsing Processing (Process S503))

After the first chemical liquid processing is performed for a predetermined time period, the discharge of the chemical liquid from the chemical liquid nozzle 71 is stopped, and a rinsing liquid (DIW) is supplied from the rinse nozzle 72 of the processing fluid supply unit 7A to the peripheral portion of the wafer W, so that a rinsing processing is performed. Through this rinsing processing, a reaction product and the chemical liquid remaining on top and bottom surfaces of the wafer W are washed away. Here, a drying processing same as will be described later (process S506) may also be performed.

(Second Chemical Liquid Processing (Process S504))

Then, a second chemical liquid processing of removing an unnecessary substance, which cannot be removed through the first chemical liquid processing, is performed on the wafer W. As in the first chemical liquid processing, the wafer W is rotated and heated, and a chemical liquid HF is supplied onto the peripheral portion of the top surface (device formation surface) of the wafer W from the chemical liquid nozzle 74 of the processing fluid supply unit 7B. As a result, an unnecessary film present on the peripheral portion of the top surface of the wafer W is removed.

(Second Rinsing Processing (Process S505))

After the second chemical liquid processing is performed for a predetermined time period, the rotation of the wafer W and the discharge of the N₂ gas from the gas discharge openings 212 and 213 are continued, whereas the discharge of the chemical liquid from the chemical liquid nozzle 74 is stopped. Then, a rinsing liquid (DIW) from the rinse nozzle 75 of the processing fluid supply unit 7B is supplied onto the peripheral portion of the wafer W, so that a rinsing processing is performed. Through this rinsing processing, a reaction product and the chemical liquid remaining on the top and bottom surfaces of the wafer W are washed away.

(Drying Processing (Process S506))

After the rinsing processing is performed for a preset time period, the rotation of the wafer W and the discharge of the N₂ gas from the gas discharge openings 212 and 213 are still continued, whereas the discharge of the rinsing liquid from the rinse nozzle 75 is stopped. Then, a drying gas (N₂ gas) is supplied from the gas nozzle 76 to the peripheral portion of the wafer W, so that a drying processing is performed.

(Wafer Carrying-Out (Process S507))

Afterwards, the cover member 5 is raised to the retreat position and the cup body 2 is lowered. Then, after the shutter 12 of the housing 11 is opened, the transfer arm (not shown) of the external wafer transfer device enters the housing 11, and the empty transfer arm is placed at a position under the wafer W held in the wafer holding unit 3 and then is raised upward. The transfer arm receives the wafer W from the wafer holding unit 3 that has stopped attracting the wafer W. Thereafter, the transfer arm holding the wafer thereon is retreated out of the housing 11. Through the above-mentioned operations, a series of liquid processings for the single sheet of wafer W is completed.

In the standard liquid processing, the above-described processing for the single sheet of wafer W is repeated twenty-five times. As already stated above, when performing the chemical liquid processing in the process S502 or the process S504, the cover member 5 suppresses the processing liquid dispersed from the wafer W from re-adhering to the top surface of the wafer W. Among the chemical liquids supplied to the wafer W from the chemical liquid nozzles 71 and 74, there may be liquid droplets that are dispersed up to the height of the cover member 5 by being bounced from the wafer W or an inner wall of the cup body 2, though the amount of these bounced liquid droplets is very small. Furthermore, there may also exist mist floating above against an air flow that is formed by the cover member 5. A part of these liquid droplets or mist may adhere to the surface of the cover member 5.

When following the above-described sequence of the processings, that is, when performing the HF chemical liquid processing after the SC1 chemical liquid processing, droplets or mist of the HF liquid may adhere to the cover member 5 after droplets or mist of the SC1 liquid adheres thereto. If these two kind of chemical liquids are mixed on the surface of the cover member 5, these chemical liquids may react with each other, so that ammonium fluoride (NH₄F) can be generated. If the above-described sequence is performed repeatedly, the amount of the generated ammonium fluoride may be increased and, finally, the generated ammonium fluoride may be crystallized. Referring to FIG. 2 and FIG. 3, an example positions to which the generated crystals adhere will be explained. In FIG. 2 and FIG. 3, crystals 601 adhere to the inner peripheral surface 51 of the cover member 5. Further, since the dispersed liquid droplets or mist may also enter a space between the cover member 5 and the outer peripheral wall 26, crystals 602 may also adhere to the outer periphery 521 of the cover member 5. Since the above-described cover member 5 is located higher than the cup body 2, the cleaning processing of these crystals with the cleaning liquid may not be performed. Even if the cleaning processing with the cleaning liquid may be performed, the cleaning liquid adhering to the cover member 5 may not be dried off thereafter.

Accordingly, in the present exemplary embodiment, by performing a heating processing for the cover member 5 in addition to the standard liquid processing, the chemical liquids adhering to the surface of the cover member 5 are removed, and the generation of the crystals can be suppressed. Further, even if the crystals already adhere to the cover member 5, the deposits can be removed by vaporizing those crystals through the heating processing.

Now, a device for deposit removal will be explained with reference to FIG. 2 and FIG. 3. As depicted in FIG. 2 in the exemplary embodiment, a heater 701 for the heating processing is provided within the cover member 5. In FIG. 3, an arrangement of the heater seen from a cross section of the cover member 5 is illustrated. In the present exemplary embodiment, a heating wiring having an oval cross-sectional shape vertically elongated from the bottom surface 52 of the cover member 5 to the top surface thereof is used. This heater is capable of increasing its temperature up to 130° C., and its operation can be controlled by the controller 8. Since the cover member 5 is formed of a high thermal conductive material, a temperature of the surface of the cover member 5 may be increased to near 130° C. after several seconds have been lapsed.

Referring to FIG. 3, it is known that the ammonium fluoride shown as the crystals 601 are thermally decomposed by being heated to 100° C. to be vaporized, though it has a solid phase at the room temperature. Further, under the condition equal to or higher than 100° C., even if the SC1 liquid and the HF liquid are mixed, they are not crystallized as ammonium fluoride. Further, before the reaction, in which the ammonium fluoride is generated, occurs, the SC1 liquid and the HF liquid are vaporized. In the heating processing of the present exemplary embodiment, the temperature or the like is set in consideration of the characteristics of the SC1 liquid, the HF liquid and the ammonium fluoride.

Now, an operation of a liquid processing including the heating processing for deposit removal according to the present exemplary embodiment will be described with reference to a flow chart of FIG. 6. This operation is conducted under the control of the controller 8. In the present exemplary embodiment, the liquid processing is performed for a single set of 25 sheets of wafers W, and the flow chart of FIG. 6 describes a processing operation for a single sheet of wafer W in the single set.

First, if the transfer arm of the external wafer transfer device is ready to carry a wafer, a wafer carrying-in operation is begun (process S601). Here, the wafer carrying-in operation is the same as the above-described wafer carrying-in operation in the process S501.

If a state shown in FIG. 1 becomes after the carrying-in of the wafer is completed, the heater 701 is driven and a heating processing is begun (process S602). This heating processing is continued until a surface temperature of the cover member 5 reaches 130° C.

Then, a first chemical liquid processing, a first rinsing processing, a second chemical liquid processing, a second rinsing processing and a drying processing are performed (processes S603 to S607). These processings are the same as the first chemical liquid processing, the first rinsing processing, the second chemical liquid processing, the second rinsing processing and the drying processing (processes S502 to S506) as described above. Further, in the first chemical liquid processing (process S603) and the second chemical liquid processing (process S605), the peripheral portion of the wafer W is heated to a temperature (e.g., 60° C.) suitable for the chemical liquid processings. In addition, since the bottom surface 52 is also heated to a high temperature through the heating of the heater 701, the peripheral portion of the wafer W may be heated by heat dissipation from the bottom surface 52 as well.

Upon the completion of the drying processing in the process S607, the heating processing is stopped by stopping the operation of the heater 701 (process S608). Thereafter, the cover member 5 is raised and the wafer is unloaded (process S609). By repeating the same liquid processing for the 25 sheets of wafers, the liquid processing for the single set of wafers is completed.

As stated above, in the present exemplary embodiment, the processing liquids such as the SC1 liquid and the HF liquid adhering to the ring-shaped surface of the cover member 5 or the crystals generated from these processing liquids are removed through the heating processing by the heater 701. Accordingly, the crystals adhering to the cover member 5 can be suppressed from being peeled off from the surface of the cover member 5 to fall down to the surface of the wafer W as particles. Further, the heating processing is performed while performing the liquid processing on the wafer W, and the heater 701 has a function of raising the temperature of the peripheral portion of the wafer W. Accordingly, heat from the heater 701 can be effectively utilized and the temperature of the peripheral portion of the wafer W can be increased more easily, so that an etching rate can be improved. Moreover, if the heat dissipation from the heater 701 is performed sufficiently, the amount of a high-temperature N₂ gas discharged from the gas discharge openings 212 and 213 may be reduced.

### Second Exemplary Embodiment

In the first exemplary embodiment, the heating processing is performed while the processing liquid is being supplied to the wafer W. If the liquid processing is performed on many sets of wafers continuously, the heater is required to be maintained powered-on for a long time, so that the power consumption is increased. In view of this problem, according to a second exemplary embodiment, the heating processing is not performed during the liquid processing, and, instead, the heating processing is performed in a standby time period after the processings on each set of wafers are completed.

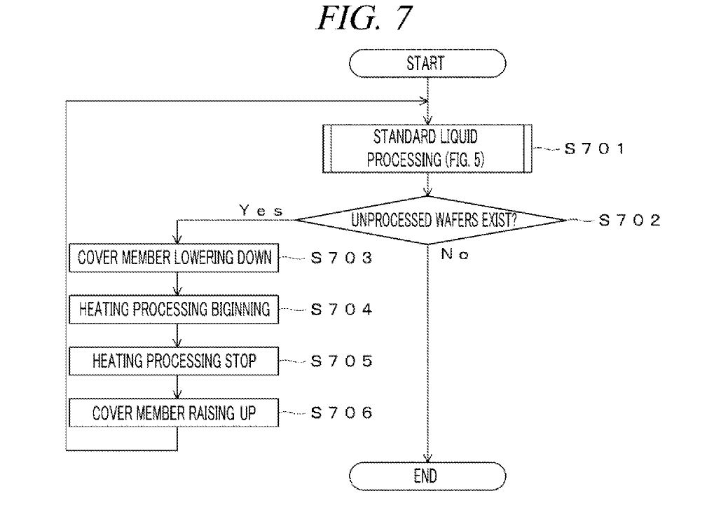

An operation of a liquid processing including a heating processing for the deposit removal according to the second exemplary embodiment will be described with reference to a flow chart of FIG. 7. This operation is performed under the control of the controller 8. In the present exemplary embodiment, the liquid processing is performed for a single set of 25 sheets of wafers, and the flow chart of FIG. 7 describes an operation for two or more sets of wafers.

First, the standard liquid processing for a single set of wafers shown in FIG. 5 is performed (process S701). In this processing, a heating processing as described in the flow chart of FIG. 6 is not performed. Thereafter, it is determined whether there exists any unprocessed set of wafers (process S702). If there is any unprocessed, the processing proceeds to the sequence of the heating processing starting from the process S703.

Since the liquid processing (process S701) for the single set of wafers is finished and the wafer transfer is completed, the cover member 5 is raised up to the retreat position. In the second exemplary embodiment, the heating processing is performed in the same state as in the case of performing the liquid processing of the wafer W shown in FIG. 1. That is, under the control of the controller 8, the cover member 5 is lowered down to be located in the same manner as illustrated in FIG. 1 (process S703). After the lowering of the cover member 5 is completed, the heater 701 is operated, and the heating processing is begun (process S704).

Dispersed liquid droplets may adhere to the surface of the cover member 5 in the liquid phase, or crystals of the ammonium fluoride crystallized from a part of the liquid droplets may adhere to the surface of the cover member 5. The heating processing is continued until both the liquid droplets and the crystals of the ammonium fluoride are removed by being vaporized. Further, at the same time the heating processing is begun, a downflow, which is the same as the downflow in the typical liquid processing, may be formed by operating the cleaning air supply unit 14. Then, the heating processing is stopped by stopping the operation of the heater (process S705). Last, the cover member 5 is raised up to the retreat position to be ready for carrying-in a next unprocessed set of wafers W (process S706).

The above-described processing is repeatedly performed on a preset number of sets of wafers W. At the process S702, if there remains no unprocessed set of the wafers, that is, if the liquid processing is performed on all sets of wafers, the series of processings is ended.

As stated above, according to the exemplary embodiment, the heating processing is performed in a standby state, where the liquid processing on the wafers W is not performed, after completing the liquid processings for the single set of wafers and before starting the liquid processings for the next unprocessed set. Accordingly, under a circumstance where the frequent crystallization of the processing liquids is suppressed, power consumption can be reduced and the liquid processing can be performed effectively. Further, since temperature control for starting and stopping the heating processing by the heater 701 only needs to be performed for every 25 sheets of wafers, not for every single wafer, it is possible to suppress a throughput of the substrate processing from being decreased. Further, this embodiment can be applied to a case of performing a liquid processing in which the peripheral portion of the wafer should not be heated excessively and, thus, a thermal influence from the heater 701 needs to be avoided. In addition, when performing the heating processing, the cover member 5 is placed, even in the standby state, at the same position as that in case of performing the liquid processing on the wafer. Accordingly, the target positions where the crystals are easily likely to be generated and where the crystals are being generated can be heated to a high temperature intensively without causing an unnecessary temperature rise of the entire housing 11. Furthermore, by forming the same downflow as that in case of the liquid processing, the vaporized processing liquids can be discharged from the exhaust path 245, and re-adhesion of the vaporized processing liquids to the inside of the housing 11 can be suppressed.

(Modification Example of Second Exemplary Embodiment)

The control of the second exemplary embodiment is performed as described above. However, the heating processing by the heater 701 may not be limited to the above example where the heating processing is performed for each single set of wafers. By way of example, the number of wafers that have been processed in the substrate processing apparatus 1 since the apparatus starts to be driven may be counted, and the same heating processing may be performed at the timing whenever 500 sheets of wafers are processed. Further, instead of the control in which the heating processing is performed based on the number of the processed wafers, the control may be performed based on an elapsed time. By way of non-limiting example, the same heating processing may be performed at the timing whenever 24 hours passes after the substrate processing apparatus 1 is driven. Furthermore, the condition such as the number of the processed wafers or the elapsed time may be stored as a fixed value by the controller 8, or without being limited thereto, a user of the apparatus may set and store appropriate values depending on the frequency of crystal growth or the like for each kind of liquid used in the liquid processings. When performing the above-described heating processing, the controller 8 monitors the preset condition such as the number of the processed wafers or the elapsed time, and if the preset condition is satisfied, the same processings as the processes S703 to S706 in FIG. 7 are performed.

In the above-described second exemplary embodiment, in case of forming the downflow when performing the heating processing, since the wafer W is not placed, gas exhaust may not be performed at the same level as that in case of performing the liquid processing. In such a case, to achieve the same exhaust state as that in case of the liquid processing, an air introduction amount of the clean air supply unit 14 may be increased to be larger than that in case of the liquid processing. Further, to achieve the same exhaust state as that in case of the liquid processing, by carrying-in a dummy wafer from the outside of the housing 11 and holding and rotating the dummy wafer under the same conditions as those in case of the liquid processing, the same air flow as that in case of the liquid processing may be formed in the vicinity of the cover member 5. In addition, if the sufficient exhaust can be performed between the clean air supply unit 14 and the exhaust port 15, the heating processing may be performed in a state where the cover member 5 keeps in a raised state without being lowered.

### Other Exemplary Embodiment

In the above, the exemplary embodiments have been described. However, the exemplary embodiments are not limiting, and various changes and modifications may be made. By way of example, although the SC1 liquid and the HF liquid are used as the processing liquids, other processing liquids may be used. For example, when continuously performing a processing with a SC1 liquid and a processing with a SC2 liquid, ammonia contained in the SC1 liquid and hydrochloric acid contained in the SC2 liquid may react with each other, so that crystals of ammonium chloride (NH₄Cl) may be generated. Even in such a case, since the ammonium chloride is vaporized at 100° C., the same effect can be achieved by performing the heating processing in the same manner as described in the above exemplary embodiments.

Further, in the above-described exemplary embodiments, the heater 701 has a vertically elongated oval cross sectional shape. However, without limited to this shape, the heater 701 may have various cross sectional shapes such as rectangle. Moreover, a multiple number of small-sized heaters may be provided respectively to correspond to positions at the inner peripheral surface 51 and positions at the outer periphery 521 which are difficult to clean by a cleaning liquid. Further, though the heater 701 is formed to have a circular ring shape, it may also possible to provide the heater only in the vicinity of the processing fluid supply units 7A and 7B where the dispersion of chemical liquids or the mist generation may easily occur. Further, the heater may be provided to heat surfaces of the recess portion 56 of the cover member 5, which face the nozzles 71, 73, 74 and 76. Further, in the above-described exemplary embodiments, the substrate processing apparatus having the ring-shaped cover member 5 is described. The heating processing in any of the exemplary embodiments, however, can be applied to an apparatus equipped with a top plate-shaped cover member that covers the entire top surface of the wafer W without being merely limited to the ring shape.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

We claim:

1. A substrate processing apparatus, comprising:
a substrate holding unit configured to hold a substrate;
a processing liquid supply unit configured to supply a processing liquid onto the substrate held in the substrate holding unit; and
a cover member which has a ring shape and is disposed to face a peripheral portion of the substrate held in the substrate holding unit,
wherein the cover member is equipped with a heater configured to heat the cover member.

2. The substrate processing apparatus of claim 1,
wherein, while a liquid processing on the substrate held in the substrate holding unit is performed, the processing liquid or crystals generated from the processing liquid which adhere to a surface of the cover member are removed through a heating processing by the heater.

3. The substrate processing apparatus of claim 2,
wherein, through the heating processing by the heater, the processing liquid or the crystals generated from the processing liquid are removed, and a temperature of the peripheral portion of the substrate is increased.

4. The substrate processing apparatus of claim 1,
wherein while a liquid processing on the substrate held in the substrate holding unit is not performed, the processing liquid or crystals generated from the processing liquid which adhere to a surface of the cover member are removed through a heating processing by the heater.

5. The substrate processing apparatus of claim 4,
wherein while the heating processing is performed, the cover member is disposed at the same position as that in case of performing the liquid processing on the substrate held in the substrate holding unit.

6. The substrate processing apparatus of claim 4,
wherein the heating processing is performed whenever the liquid processing on a preset number of substrates is finished.

7. The substrate processing apparatus of claim 4,
wherein the heating processing is performed whenever a liquid processing on the substrate is performed for a preset time period.

8. The substrate processing apparatus of claim 1,
wherein the heater is embedded in the cover member and formed along the ring shape of the cover member.

9. The substrate processing apparatus of claim 1,
wherein the heater is configure to heat an inner peripheral surface of the cover member.

10. A deposit removing method of removing a deposit of a substrate processing apparatus including a substrate holding unit that holds a substrate; a processing liquid supply unit that supplies a processing liquid onto the substrate held in the substrate holding unit; and a cover member that has a ring shape and is disposed to face a peripheral portion of the substrate held in the substrate holding unit,
wherein a heater provided in the cover member heats the cover member.

11. A computer-readable recording medium having stored thereon computer-executable instructions that, in response to execution, perform a deposit removing method of removing a deposit of a substrate processing apparatus including a substrate holding unit that holds a substrate; a processing liquid supply unit that supplies a processing liquid onto the substrate held in the substrate holding unit; and a cover member that has a ring shape and is disposed to face a peripheral portion of the substrate held in the substrate holding unit,
wherein the deposit removing method includes heating the cover member by a heater provided in the cover member.
